(19) United States
(12) Patent Application Publication
(10) Pub. No.: US 2025/0349655 A1
(43) Pub. Date: Nov. 13, 2025

(54) OPTICAL MODULE

(71) Applicants: InnoLight Technology (Suzhou) Ltd., Suzhou , Jiangsu (CN); TERAHOP PTE. LTD., SINGAPORE (SG)

(72) Inventors: Chunxue Hu, Suzhou , Jiangsu (CN); Changwu Lu, Suzhou , Jiangsu (CN); Anli Li, Suzhou , Jiangsu (CN); Xiaolong Zhang, Suzhou , Jiangsu (CN)

(21) Appl. No.: 18/870,466

(22) PCT Filed: Apr. 27, 2023
(86) PCT No.: PCT/CN2023/091042

§ 371 Date: Nov. 29, 2024

(30) Foreign Application Priority Data
Jun. 1, 2022 (CN) 202210617124.9

(51) Int. Cl. H01L 23/367; H10F 77/60; H10H 29/85

(52) U.S. Cl. CPC H01L 23/3675; H10F 77/60; H10H 29/8582

(57) ABSTRACT

The present application provides an optical module. The optical module comprises: a housing assembly; an optical assembly, disposed in the housing assembly; and a heat dissipation elastic sheet, sandwiched between the optical assembly and the housing assembly. The heat dissipation elastic sheet comprises a heat dissipation portion, and the heat dissipation portion is in contact with the optical assembly. The heat dissipation elastic sheet further comprises a deformation portion, the deformation portion is connected to the heat dissipation portion, and the deformation portion is bent relative to the heat dissipation portion. The deformation portion is provided with a hollow area, so that the deformation portion can be bent and deformed. In this way, the heat dissipation elastic sheet of the present application is convenient for secondary disassembly and assembly, and can be in elastic contact with an element to be cooled, thereby avoiding adverse effects as much as possible on performance of the element to be cooled due to excessive stress of the element to be cooled.

### CROSS-REFERENCE TO RELATED PATENT APPLICATION

This application claims priority to the Chinese patent application filed with the China Patent Office on Jun. 1, 2022, with the application number 202210617124.9 and the invention name “Optical Module”, the entire content of which is incorporated into this application by reference.

### FIELD OF THE DISCLOSURE

This application relates to the field of heat dissipation technology for optical communication equipment, and specifically relates to an optical module.

### BACKGROUND TECHNIQUE

In recent years, the global cloud computing data center market has continued to expand, 5G telecommunications network construction is in full swing, and the market demand for high-speed optical modules is also increasing. Various series and types of products have been launched one after another to provide cloud computing data centers, wireless access, and transmission, offering the best optical module solutions to customers in other fields.

Optical modules are optoelectronic devices that perform optical-to-electrical and electro-to-optical conversion. The optical module needs heat dissipation to ensure stable light emission, which is crucial for normal operation. However, due to objective factors, it is often necessary to disassemble and reassemble the optical assembly inside the module. In this process, heat dissipation materials commonly used are restricted by factors such as material properties and size limitations. Consequently, problems such as difficulty in cleaning, material damage, and lack of reusability during the disassembly process are inevitable. Additionally, this often leads to high labor costs, and insufficient cleaning can affect the overall performance of the optical module. Furthermore, conventional heat dissipation elements cannot provide elastic contact with the optical assembly, which can result in excessive force on the components and adversely affect their performance.

### SUMMARY OF THE DISCLOSURE

### Technical Problem

This application provides an optical module. The heat dissipation elastic sheet is easy to disassemble and reassemble and can provide elastic contact with the heat-dissipating components to avoid excessive force on them and minimize adverse effects on their performance.

### Technical Solutions

This application provides an optical module. The optical module includes: a housing assembly; an optical assembly located in the housing assembly; and a heat dissipation elastic sheet sandwiched between the optical assembly and the housing assembly. The heat dissipation elastic sheet includes a heat dissipation portion, and the heat dissipation portion is in contact with the optical assembly. The heat dissipation elastic sheet further includes a deformation portion, the deformation portion is connected to the heat dissipation portion, and the deformation portion is bent relative to the heat dissipation portion. Wherein, the deformation portion is provided with a hollow area so that the deformation portion can bend and deform.

In an embodiment of the present application, the heat dissipation portion is provided with a hollow area.

In an embodiment of the present application, the hollow area of the heat dissipation portion and the hollow area of the deformation portion are connected with each other.

In an embodiment of the present application, a number of the hollow areas is at least two; each of the hollow areas extends along a first direction, and at least two of the hollow areas are sequentially spaced apart along a second direction; wherein, the first direction intersects the second direction, and both the first direction and the second direction are parallel to the heat dissipation portion, and the heat dissipation portion and the deformation portion are arranged oppositely along the first direction or the second direction.

In an embodiment of the present application, an area occupied by the hollow area is 10% to 90% of a total area of the heat dissipation elastic sheet.

In an embodiment of the present application, the housing assembly is provided with a limiting groove; and the heat dissipation elastic sheet is embedded in the limiting groove and used to limit a position of the heat dissipation elastic sheet in the housing assembly.

In an embodiment of the present application, the optical assembly includes: an optoelectronic chip; a heat sink, wherein the optoelectronic chip is arranged on the heat sink; wherein, the optical assembly is fastened to the housing assembly, so that the heat dissipation portion is in close contact with the heat sink, and heat generated by the optoelectronic chip is sequentially dissipated to the housing assembly through the heat sink and the heat dissipation elastic sheet.

In an embodiment of the present application, the heat dissipation elastic sheet further includes a support portion; opposite sides of the heat dissipation portion are connected to the support portion through different deformation portions; wherein, a thickness of the heat dissipation portion, a thickness of the deformation portion and a thickness of the support portion increase in sequence.

In an embodiment of the present application, the heat dissipation elastic sheet further includes a support portion; the support portion is connected to the heat dissipation portion through the deformation portion, the deformation portion forms a first included angle with a third direction, and the support portion forms a second included angle with the third direction; wherein, the third direction is perpendicular to the heat dissipation portion, the first included angle and the second included angle are both greater than 0° and less than 90°, and the first included angle is smaller than the second included angle.

In an embodiment of the present application, the optical module includes at least two heat dissipation elastic sheets.

### Beneficial Effects

The beneficial effects of this application, different from existing technology, are as follows: This application provides an optical module where the heat dissipation elastic sheet is an independent entity. When used to dissipate heat from the heat-dissipating component (such as an optical assembly in an optical module), it needs only to be in direct physical contact with the heat-dissipating component. This means the heat dissipation elastic sheet is easy to disassemble and reassemble, making it convenient to use and reusable.

Furthermore, the heat dissipation elastic sheet includes a heat dissipation portion and a deformation portion bent relative to the heat dissipation portion. At least the deformation portion includes a hollow area. In this application, the hollow area reduces the rigidity and improves the flexibility of the deformation portion, making the deformation portion easier to bend and deform. This allows the heat dissipation elastic sheet to provide elastic contact with the heat-dissipating component, thereby minimizing excessive stress on the cooling element and preventing adverse effects on its performance.

### BRIEF DESCRIPTION OF THE DRAWINGS

In order to more clearly illustrate the technical solutions in the embodiments of the present application, the drawings needed to be used in the description of the embodiments will be briefly introduced below. Obviously, the drawings in the following description are only some embodiments of the present application. For those skilled in the art, other drawings can also be obtained based on these drawings without exerting creative efforts.

FIG. 1 is a schematic structural diagram of an embodiment of the optical module of the present application;

FIG. 2 is a schematic structural diagram of the assembly of the heat dissipation elastic sheet in the housing assembly of the present application;

FIG. 3 is a schematic structural diagram of the first embodiment of the heat dissipation elastic sheet of the present application;

FIG. 4 is a schematic side structural view of the heat dissipation elastic sheet shown in FIG. 3;

FIG. 5 is a schematic structural diagram of the second embodiment of the heat dissipation elastic sheet of the present application;

FIG. 6 is a schematic structural diagram of the third embodiment of the heat dissipation elastic sheet of the present application; and

FIG. 7 is a schematic structural diagram of an embodiment of the heat dissipation elastic sheet assembly of the present application.

### EXPLANATION OF REFERENCE NUMERALS

heat dissipation elastic sheet 10, heat dissipation portion 11, deformation portion 12, hollow area 13, support portion 14; first direction X, second direction Y, third direction Z; heat dissipation elastic sheet assembly 20; optical module 30, housing assembly 31, optical assembly 32, circuit board 321, heat sink 322, optical interface 323, limiting slot 33.

### DETAILED DESCRIPTION OF THE EXEMPLARY EMBODIMENTS

The technical solutions in the embodiments of the present application will be clearly and completely described below with reference to the accompanying drawings. Obviously, the described embodiments are only some of the embodiments of the present application, and not all of them. Based on the embodiments in this application, all other embodiments obtained by those skilled in the art without making creative efforts fall within the scope of protection provided by this application. In addition, it should be understood that the specific embodiments described here are only used to illustrate and explain the application, and are not used to limit it. Unless otherwise stated, the directional terms such as ‘upper,’ ‘lower,’ ‘left,’ and ‘right’ generally refer to the upper, lower, left, and right positions of the device in its actual use or working state, specifically based on the drawing direction in the attached drawings.

This application provides an optical module, which will be described in detail below. It should be noted that the order in which the following embodiments are described does not limit the preferred order of the embodiments in the present application. In the following embodiments, each has its own emphasis. For parts not described in detail in a certain embodiment, refer to the relevant descriptions in other embodiments.

In order to solve the technical problems in the prior art that the heat dissipation material used in optical modules is inconvenient for secondary disassembly and assembly and cannot provide elastic contact to optical assembly, an embodiment of the present application provides an optical module. The optical module includes: a housing assembly; an optical assembly located in the housing assembly; and a heat dissipation elastic sheet sandwiched between the optical assembly and the housing assembly. The heat dissipation elastic sheet includes a heat dissipation portion, and the heat dissipation portion is in contact with the optical assembly. The heat dissipation elastic sheet further includes a deformation portion, the deformation portion is connected to the heat dissipation portion, and the deformation portion is bent relative to the heat dissipation portion. Wherein, the deformation portion is provided with a hollow area so that the deformation portion can bend and deform. This is explained in detail below.

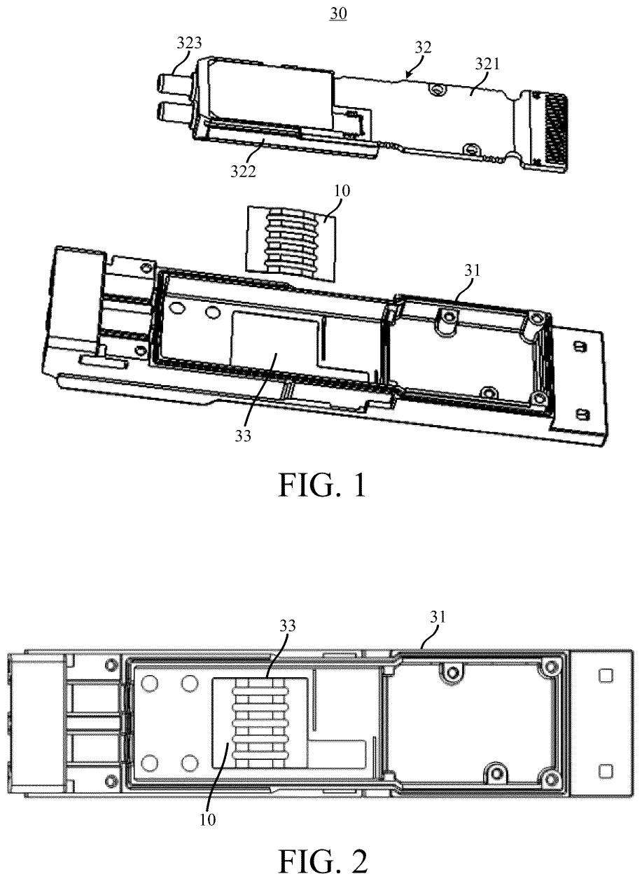

Please refer to FIG. 1 and FIG. 2. FIG. 1 is a schematic structural diagram of an embodiment of the optical module of the present application. FIG. 2 is a schematic structural diagram of the assembly of the heat dissipation elastic sheet in the housing assembly of the present application.

In an embodiment, the optical module 30 includes a housing assembly 31 and an optical assembly 32. The housing assembly 31 serves as the basic carrier of the optical module 30 and consists of an upper housing and a lower housing. The upper and lower housings are joined together to form a space that accommodates the optical assembly 32. Only the lower housing is shown here.

The housing assembly 31 serves to carry and protect the components of the optical module 30, including the optical assembly 32. The optical assembly 32 is the core component of the optical module 30 that performs optical-to-electrical and/or electrical-to-optical conversion. The optical assembly 32 includes a circuit board 321, an optoelectronic chip, a heat sink 322, and an optical interface 323. The optoelectronic chip is mounted on the heat sink 322, and through the heat sink, the optoelectronic chip dissipates heat to the housing assembly 31. The specific working principle of the optical assembly 32 is well understood by those skilled in the art and will not be described in detail here.

The optical module 30 further includes a heat dissipation elastic sheet 10. The heat dissipation elastic sheet 10 is sandwiched between the housing assembly 31 and the optical assembly 32, that is, between the heat sink 322 and the housing assembly 31. The heat dissipation elastic sheet 10 is in contact with the housing assembly 31 and the optical assembly 32 respectively, and the heat generated by the operation of the optical assembly 32 is conducted to the housing assembly 31 through the heat dissipation elastic sheet 10 for heat dissipation.

It should be noted that the heat dissipation material used in the traditional optical module 30, such as heat dissipation glue, usually needs to be heated after assembly so that the material melts and then solidifies, allowing it to cover the optical assembly 32 and achieve the desired heat dissipation effect. However, the optical assembly 32 in the optical module 30 often needs to be disassembled and reassembled. During this process, the cured heat dissipation material easily separates from the optical assembly 32 and the housing assembly 31, greatly reducing the heat dissipation effect. The disassembled heat dissipation material cannot be reused, which requires cleaning the remaining material between the optical assembly 32 and the housing assembly 31 and reinstalling new heat dissipation material. Cleaning a large area of heat dissipation material will lead to significant work difficulties and cost issues, particularly in terms of time and manpower consumption.

In view of this, the heat dissipation elastic sheet 10 in this embodiment is separate from both the housing assembly 31 and the optical assembly 32. That is, the heat dissipation elastic sheet 10 is detachably provided between the housing assembly 31 and the optical assembly 32. The heat dissipation elastic sheet 10 in this embodiment is an independent entity. It is used to directly physically contact the optical assembly 32 when dissipating heat from the heat dissipation component to be treated (with the optical assembly 32 of the optical module 30 taken as an example in this embodiment) without the need for heating or curing. No auxiliary assembly jig is needed during the process of assembling the heat dissipation elastic sheet 10. When it is necessary to reassemble the optical assembly 32, the heat dissipation elastic sheet 10 can be directly removed without any cleaning work. In other words, the heat dissipation elastic sheet 10 of this embodiment is easy to reassemble, convenient to use, and allows reuse, which helps to reduce the difficulty of heavy work and decreases working hours and labor costs.

Optionally, the heat dissipation elastic sheet 10 can be made of a material with good thermal conductivity, such as copper or steel. In other words, the material used for the heat dissipation elastic sheet 10 in this embodiment is not a small-molecule volatile substance. Even if it is used for a long period, there will be no risk of volatile oil leakage. Therefore, problems such as changes in the physical properties of the material caused by being in a high-temperature environment over a long period can be avoided.

Further, the housing assembly 31 is provided with a limiting groove 33. When the heat dissipation elastic sheet 10 is assembled to the housing assembly 31, the heat dissipation elastic sheet 10 is embedded in the limiting groove 33. The limiting groove 33 is used to limit the position of the heat dissipation elastic sheet 10 in the housing assembly 31.

The assembly process of the optical module 30 in this embodiment is as follows: first, the heat dissipation elastic sheet 10 is embed in the limiting groove 33 of the housing assembly 31, so as to assemble the heat dissipation elastic sheet 10 to the housing assembly 31; and then the optical assembly 32 is assembled in the housing assembly 31. The optical assembly 32 and the housing assembly 31 work together to compress the heat dissipation elastic sheet 10, which can prevent the heat dissipation elastic sheet 10 from protruding from the limiting groove 33. At the same time, the limiting groove 33 restricts the position of the heat dissipation elastic sheet 10, thereby fixing the heat dissipation elastic sheet 10 in the optical module 30.

The heat dissipation elastic sheet of the embodiment of the present application will be described in detail below.

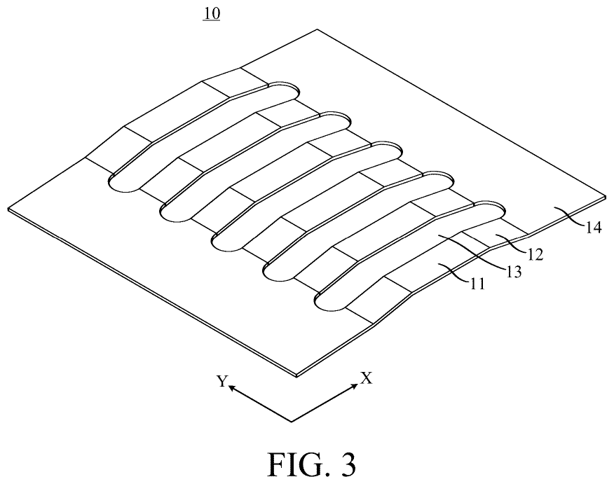

Please refer to FIG. 3, which is a schematic structural diagram of the heat dissipation elastic sheet according to the first embodiment of the present application.

In one embodiment, the heat dissipation elastic sheet 10, as its name implies, has certain elastic deformation ability. When the heat dissipation elastic sheet 10 is sandwiched between the housing assembly and the optical assembly, the heat dissipation elastic sheet 10 can elastically deform, so that the heat dissipation elastic sheet 10 is in close contact with the optical assembly, ensuring that the heat generated by the operation of the optical assembly can be efficiently conducted to the heat dissipation elastic sheet 10 for heat dissipation. Moreover, the heat dissipation elastic sheet 10 can provide elastic contact to the optical assembly, so as to avoid excessive force on the optical assembly and adverse effects on its performance.

Specifically, the heat dissipation elastic sheet 10 includes a heat dissipation portion 11. The heat dissipation portion 11 is used to contact the components to be heat dissipated, such as optical assemblies, heat sinks, etc., so that the heat of the optical assembly 32 can be conducted to the heat dissipation elastic sheet 10 through the heat dissipation portion 11 for heat dissipation. For example, as shown in FIG. 1, the optical interface 323 of the optical assembly 32 is fixed at a corresponding position on the housing assembly 31, and the optical assembly 32 is locked to the housing assembly 31 through fasteners such as screws, so that the heat sink 322 of the optical assembly 32 squeezes the heat dissipation elastic sheet 10. At this time, the heat dissipation elastic sheet 10 undergoes elastic deformation so that the heat dissipation portion 11 is in close contact with the heat sink 322, which can ensure the heat dissipation effect.

The heat dissipation elastic sheet 10 further includes a deformation portion 12. The deformation portion 12 is connected to the heat dissipation portion 11 and is bent at a certain angle relative to the heat dissipation portion 11, with the angle being greater than 0° and less than 180°. When the heat dissipation elastic sheet 10 is assembled on the optical module, the heat dissipation portion 11 of the heat dissipation elastic sheet 10 is in contact with the optical assembly, and the deformation portion 12 is located on the side of the heat dissipation portion 11 away from the optical assembly.

For example, both the heat dissipation portion 11 and the deformation portion 12 may be in the shape of a flat plate. When the heat dissipation elastic sheet 10 is not assembled on the optical module, the plane of the heat dissipation portion 11 and the plane of the deformation portion 12 form an included angle θ3, which is greater than 0° and less than 180°. It is understood that both the heat dissipation portion 11 and the deformation portion 12 are flat plates. The thickness of different areas of the heat dissipation portion 11 and the deformation portion 12 does not need to be consistent, and variations are allowed.

In this embodiment, the deformation portion 12 is provided with a hollow area 13. The hollow area 13 penetrates the deformation portion 12 along its thickness. The hollow area 13 in this embodiment weakens the rigidity of the deformation portion 12 and improves its ability to deform, making it easier to bend and deform. This ensures that the heat dissipation elastic sheet 10 can provide elastic contact with the optical assembly and avoids excessive stress that could negatively impact the performance of the optical assembly.

Furthermore, the heat dissipation portion 11 and the deformation portion 12 form the raised part of the heat dissipation elastic sheet 10. In this embodiment, in addition to the deformation portion 12 having a hollow area 13, the heat dissipation portion 11 also has a hollow area 13. The hollow area 13 in the heat dissipation portion 11 penetrates it along its thickness, and the hollow areas 13 in both the heat dissipation portion 11 and the deformation portion 12 are connected to each other.

Through this method, the hollow area 13 in the heat dissipation portion 11 weakens its rigidity and improves the deformation ability of the raised part of the heat dissipation elastic sheet 10, making it easier to bend and deform. This ensures that the heat dissipation elastic sheet 10 can provide elastic contact with the optical assembly, preventing excessive force that could negatively affect its performance.

In one embodiment, the number of hollow areas 13 is at least two. Each hollow area 13 extends along the first direction X, and the at least two hollow areas 13 are sequentially spaced apart along the second direction Y, where the first direction X intersects the second direction Y. Furthermore, when the heat dissipation portion 11 is flat, both the first direction X and the second direction Y are parallel to the plane of the heat dissipation portion 11. The heat dissipation portion 11 and the deformation portion 12 are arranged opposite to each other along the first direction X or the second direction Y.

FIG. 3 exemplarily shows the configuration where the heat dissipation portion 11 and the deformation portion 12 are arranged along the first direction X. Moreover, FIG. 3 also exemplarily shows that both the heat dissipation portion 11 and the deformation portion 12 are provided with hollow areas 13, and the hollow areas 13 in the heat dissipation portion 11 and the deformation portion 12 are connected, meaning each hollow area 13 spans both the heat dissipation portion 11 and the deformation portion 12. The at least two hollow areas 13 of the heat dissipation elastic sheet 10 are arranged sequentially.

The hollow area 13 extending along the first direction X should be understood to mean that the hollow area 13 extends generally along the first direction X, with the possibility of inclined extensions of the hollow area 13 along this direction.

In one embodiment, the heat dissipation elastic sheet 10 further includes a support portion 14. Opposite sides of the heat dissipation portion 11 are connected to support portions 14 through deformation portions 12. The heat dissipation elastic sheet 10 contacts the housing assembly of the optical module through the support portion 14, and the heat transferred from the optical assembly to the heat dissipation elastic sheet 10 is further conducted to the housing assembly through the support portion 14. In the embodiment, the support portion 14 increases the contact area between the heat dissipation elastic sheet 10 and the housing assembly, improving the heat dissipation effect.

For example, as shown in FIG. 3, when the heat dissipation portion 11 and the deformation portion 12 are oppositely arranged along the first direction X, the heat dissipation portion 11 is connected to one support portion 14 on one side through the deformation portion 12, and to another support portion 14 on the other side through another deformation portion 12. Each hollow area 13 spans the heat dissipation portion 11 and the deformation portions 12 on both sides of the heat dissipation portion 11.

Certainly, in other embodiments, the support portion 14 may be omitted, meaning the heat dissipation elastic sheet 10 consists only of the heat dissipation portion 11 and the deformation portion 12, with contact to the housing assembly achieved through the deformation portion 12.

In one embodiment, the thickness of the heat dissipation portion 11, the thickness of deformation portion 12, and the thickness of support portion 14 increase progressively. This ensures that the heat dissipation portion 11 and the deformation portion 12 retain sufficient deformation ability, while the heat dissipation elastic sheet 10 maintains adequate support strength.

Furthermore, the thickness of the deformation portion 12 can gradually increase from the heat dissipation portion 11 to the support portion 14, providing a smooth transition between these portions.

In one embodiment, the area occupied by the hollow area 13 is 10% to 90% of the total area of the heat dissipation elastic sheet 10, such as 10%, 20%, 30%, 40%, 50%, 60%, 70%, 80% %, 90%, etc. In this way, it can not only ensure that the hollow area 13 has a sufficient area so that the heat dissipation elastic sheet 10 has sufficient deformation ability, but also ensure that there is a sufficient contact area between the heat dissipation elastic sheet 10 and the optical assembly to ensure the heat conduction efficiency and ensure that the heat dissipation elastic sheet 10 has sufficient support strength to avoid reliability problems of the heat dissipation elastic sheet 10.

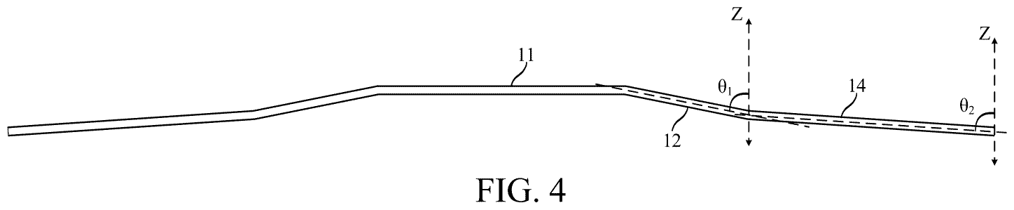

Please also refer to FIG. 4, which is a schematic side structural view of the heat dissipation elastic sheet shown in FIG. 3.

In one embodiment, the deformation portion 12 and the third direction Z form a first included angle θ1. The third direction Z is perpendicular to the heat dissipation portion 11. In the case where the heat dissipation portion 11 is flat, the third direction Z is perpendicular to the plane where the heat dissipation portion 11 is located.

The first included angle θ1 is greater than 0° and less than 90°. Furthermore, the angle between the deformation portion 12 and the heat dissipation portion 11 may be an acute angle or an obtuse angle. Preferably, as shown in FIG. 4, the angle between the deformation portion 12 and the heat dissipation portion 11 is an obtuse angle, so that when the heat dissipation elastic sheet 10 is extruded and deformed, the heat dissipation portion 11 and the support portion 14 will not overlap, which can reduce the overall thickness of the heat dissipation elastic sheet 10. Since the space between the optical assembly and the housing assembly for assembling the heat dissipation elastic sheet 10 is limited, the overall thickness of the heat dissipation elastic sheet 10 in this embodiment is smaller, which is more conducive to application in optical modules and can be adapted to more types of optical modules.

In one embodiment, the support portion 14 and the third direction Z form a second included angle θ2. The second included angle θ2 is greater than 0° and less than 90°. Preferably, the angle between the support portion 14 and the heat dissipation portion 11 is an obtuse angle. In this way, after the heat dissipation elastic sheet 10 is extruded and deformed, the originally inclined support portion 14 can be flattened, so that the contact area between the support portion 14 and the housing assembly is increased as much as possible, thereby improving the heat dissipation effect of the heat dissipation elastic sheet 10.

The first included angle θ1 formed between the deformation portion 12 and the third direction Z is smaller than the second included angle θ2 formed between the support portion 14 and the third direction Z. Compared with the situation where the first included angle θ1 is greater than the second included angle θ2, in this embodiment the first included angle θ1 is smaller than the second included angle θ2, that is, the degree of inclination of the deformation portion 12 relative to the heat dissipation portion 11 is greater than that of the support portion 14, so that it is easier for the support portion 14 to be flattened after the heat dissipation elastic sheet 10 is extruded and deformed, which further helps to improve the heat dissipation effect of the heat dissipation elastic sheet 10.

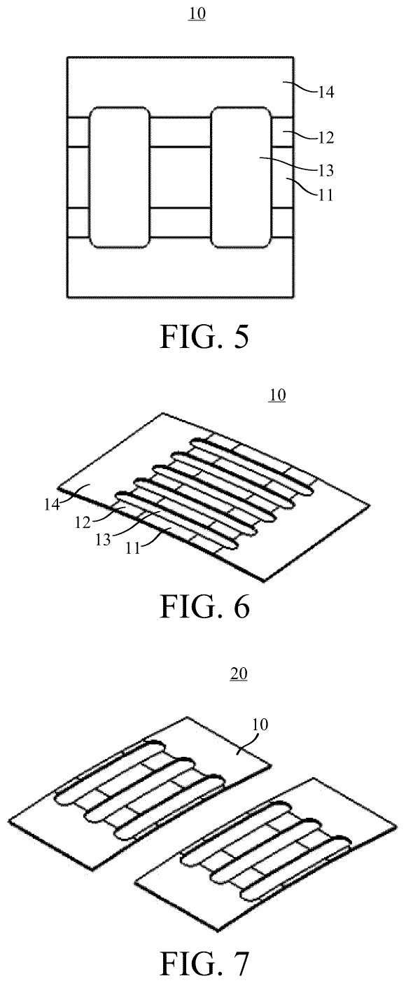

It should be noted that the number of hollow areas 13, the width and length of the hollow areas 13, and the bending angles of the deformation portion 12 and the support portion 14 can all be set appropriately as needed. FIG. 5 and FIG. 6 show that the heat dissipation elastic sheet 10 has different numbers of hollow areas 13, hollow areas 13 of different widths and lengths, and deformation portions 12 and support portions 14 with different bending angles.

Moreover, FIGS. 3 to 6 show that the heat dissipation elastic sheet 10 has a symmetrical structure about a plane, and the plane is perpendicular to the first direction X or the second direction Y. It can be understood that the heat dissipation elastic sheet 10 in the embodiment of the present application is not limited to the symmetrical structure shown in FIGS. 3 to 6, and the heat dissipation elastic sheet 10 may have other forms of symmetrical structures, or even an asymmetric structure. The structural form of the heat dissipation elastic sheet 10 can be reasonably selected according to the characteristics of the optical module to which the heat dissipation elastic sheet 10 is applied.

Please refer to FIG. 7, which is a schematic structural diagram of a heat dissipation elastic sheet assembly according to an embodiment of the present application.

In one embodiment, the heat dissipation elastic sheet assembly 20 includes at least two heat dissipation elastic sheets 10. The heat dissipation elastic sheet 10 has been described in detail in the above embodiment, and will not be described again here. In other words, the heat dissipation elastic sheet 10 in this embodiment adopts a split design, that is, at least two heat dissipation elastic sheets 10 are used in the form of components. For example, at least two heat dissipation elastic sheets 10 of the heat dissipation elastic sheet assembly 20 are assembled in the optical module. Different heat dissipation elastic sheets 10 can be used for heat dissipation in different areas of the optical assembly. In this embodiment, the heat dissipation elastic sheet assembly 20 uses multiple heat dissipation elastic sheets 10 to greatly improve the heat dissipation effect of the optical module.

To sum up, the optical module provided by this application and the heat dissipation elastic sheet and the heat dissipation elastic sheet assembly used therein are provided. This application provides an optical module where the heat dissipation elastic sheet is an independent entity. When used to dissipate heat from the heat-dissipating component (such as an optical assembly in an optical module), it needs only to be in direct physical contact with the heat-dissipating component. This means the heat dissipation elastic sheet is easy to disassemble and reassemble, making it convenient to use and reusable.

Furthermore, the heat dissipation elastic sheet includes a heat dissipation portion and a deformation portion bent relative to the heat dissipation portion. At least the deformation portion includes a hollow area. In this application, the hollow area reduces the rigidity and improves the flexibility of the deformation portion, making the deformation portion easier to bend and deform. This allows the heat dissipation elastic sheet to provide elastic contact with the heat-dissipating component, thereby minimizing excessive stress on the cooling element and preventing adverse effects on its performance.

The optical module provided by this application has been introduced in detail above. Specific examples are used in this article to illustrate the principles and implementation methods of this application. The description of the above embodiments is only used to help understand the method and its core idea of this application; at the same time, for those of ordinary skill in the art, there will be changes in the specific implementation and application scope based on the ideas of this application. In summary, the content of this description should not be understood as a limitation of this application.

1. An optical module, characterized by including:
a housing assembly;
an optical assembly, disposed in the housing assembly;
and a heat dissipation elastic sheet, sandwiched between the optical assembly and the housing assembly;
wherein, the heat dissipation elastic sheet comprises:
a heat dissipation portion in contact with the optical assembly;
a deformation portion connected to the heat dissipation portion, and the deformation portion bent relative to the heat dissipation portion, and
the deformation portion provided with a hollow area, so that the deformation portion is bent and deformed.

2. The optical module according to claim 1, characterized in that, the heat dissipation portion is provided with the hollow area.

3. The optical module according to claim 2, characterized in that, the hollow area of the heat dissipation portion and the hollow area of the deformation portion are connected with each other.

4. The optical module according to claim 1, characterized in that, a number of the hollow areas is at least two;
each of the hollow areas extends along a first direction, and at least two of the hollow areas are sequentially spaced apart along a second direction;
wherein, the first direction intersects the second direction, and both the first direction and the second direction are parallel to the heat dissipation portion, and the heat dissipation portion and the deformation portion are arranged oppositely along the first direction or the second direction.

5. The optical module according to claim 1, characterized in that, an area occupied by the hollow area is 10% to 90% of a total area of the heat dissipation elastic sheet.

6. The optical module according to claim 1, characterized in that, the housing assembly is provided with a limiting groove; and
the heat dissipation elastic sheet is embedded in the limiting groove and used to limit a position of the heat dissipation elastic sheet in the housing assembly.

7. The optical module according to claim 1, characterized in that, the optical assembly includes:
an optoelectronic chip;
a heat sink, wherein the optoelectronic chip is arranged on the heat sink;
wherein, the optical assembly is fastened to the housing assembly, so that the heat dissipation portion is in close contact with the heat sink, and heat generated by the optoelectronic chip is sequentially dissipated to the housing assembly through the heat sink and the heat dissipation elastic sheet.

8. The optical module according to claim 1, characterized in that, the heat dissipation elastic sheet further includes a support portion;
opposite sides of the heat dissipation portion are connected to the support portion through different deformation portions;
wherein, a thickness of the heat dissipation portion, a thickness of the deformation portion and a thickness of the support portion increase in sequence.

9. The optical module according to claim 1, characterized in that, the heat dissipation elastic sheet further includes a support portion;
the support portion is connected to the heat dissipation portion through the deformation portion, the deformation portion forms a first included angle with a third direction, and the support portion forms a second included angle with the third direction;
wherein, the third direction is perpendicular to the heat dissipation portion, the first included angle and the second included angle are both greater than 0° and less than 90°, and the first included angle is smaller than the second included angle.

10. The optical module according to claim 1, characterized in that, the optical module includes at least two heat dissipation elastic sheets.
